(19) United States
(12) Patent Application Publication
(10) Pub. No.: US 2022/0190263 A1
(43) Pub. Date: Jun. 16, 2022

(54) DISPLAY PANEL AND DISPLAY APPARATUS

(71) Applicant: BOE TECHNOLOGY GROUP CO., LTD., Beijing (CN)

(72) Inventors: Shengguang Ban, Beijing (CN); Zhanfeng Cao, Beijing (CN); Ke Wang, Beijing (CN); Pinfan Wang, Beijing (CN)

(73) Assignee: BOE TECHNOLOGY GROUP CO., LTD., Beijing (CN)

(21) Appl. No.: 17/279,782

(22) PCT Filed: Jun. 2, 2020
(86) PCT No.: PCT/CN2020/093902

§ 371 Date: Mar. 25, 2021

(51) Int. Cl. H01L 51/00

(52) U.S. Cl. CPC H01L 51/0097; H01L 2251/5338

(57) ABSTRACT

A display panel is provided. The display panel may include a flexible substrate (100) including a display region (20) and a dummy region (22). The dummy region (22) may be at periphery of the display region (20). The display region (20) may include a plurality of display islands (26), a plurality of first openings (28) surrounding each of the plurality of display islands (26), a plurality of first bridges (30) connecting the plurality of display islands (26), and a plurality of display units on the plurality of display islands (26), respectively. The dummy region (22) may include a plurality of dummy islands, a plurality of dummy openings surrounding each of the plurality of dummy islands, and a plurality of dummy bridges connecting the plurality of dummy islands. The dummy region (22) may not include display units.

### TECHNICAL FIELD

The present disclosure relates to display technologies and, in particular, to a display panel and a display apparatus.

### BACKGROUND

With the development of display technology, organic light-emitting diode (OLED) displays are gradually replacing liquid-crystal display (LCDs). Because of a wide viewing angle, improved image quality, low power consumption, and general suitability of foldable displays, OLED displays start to become very popular among consumers, especially for use in portable and wearable applications.

The development of OLEDs expands their application from flat, rigid displays to flexible displays to meet emerging demands. Electronic components such as light-emitting diodes and their electrical connections can be fabricated on a flexible substrate that allows the displays to be bent.

### BRIEF SUMMARY

One embodiment of the present disclosure is a display panel. The display panel may include a flexible substrate comprising a display region and a dummy region; the dummy region being at periphery of the display region; the display region comprising a plurality of display islands, a plurality of first openings surrounding each of the plurality of display islands, a plurality of first bridges connecting the plurality of display islands, and a plurality of display units on the plurality of display islands, respectively. The dummy region may further include a plurality of dummy islands, a plurality of dummy openings surrounding each of the plurality of dummy islands, and a plurality of dummy bridges connecting the plurality of dummy islands, and the dummy region may not include display units.

Optionally, an area of the first openings per unit area in the display region may be substantially the same as an area of the dummy openings per unit area in the dummy region.

Optionally, the plurality of first openings may be arranged in the display region in a substantially same pattern as the plurality of dummy openings in the dummy region.

Optionally, one of the plurality of dummy openings may have a substantially same shape and size as one of the plurality of first openings.

Optionally, a width of one of the plurality of dummy bridges may be larger than a width of one of the plurality of first bridges.

Optionally, a width of one of the plurality of dummy bridges located closer to the display region may be smaller than a width of one of the plurality of dummy bridges located farther away from the display region.

Optionally, widths of the plurality of dummy bridges may increase as distances of the plurality of dummy bridges from the display region increase.

Optionally, each of the plurality of first openings may have an oblong shape having a length less than 1000 μm and a width less than 100 μm, each of the plurality of display islands may have a square shape having a side approximately in a range of 200 μm to 600 μm, and a width of each of the plurality of first bridges may be approximately in a range of 10 μm to 50 μm.

Optionally, a width of the dummy region may not be less than 100 μm.

Optionally, each of the plurality of first bridges may include an arc shape connecting adjacent display islands and a force compensation area at an inner side and a middle part of the arc shape, and the force compensation area may be configured to reduce stress at the middle part of each of the plurality of first bridges.

Optionally, a width of each of the first bridges may be at a maximum at the middle thereof.

Optionally, an inner side of the force compensation area may be a straight line.

Optionally, the force compensation area may have a rectangular shape or a partial circular shape.

Optionally, a width of contact area between a first bridge and a first island may be larger than a width of the arc shape of the first bridge, and may not be more than an inner radius of the arc shape.

Optionally, the contact area between the first bridge and the first island may be reinforced by employing a fillet or a chamfer.

Optionally, the display panel may further include a non-opening region on a side of the dummy region opposite from the display region. The non-opening region may not include an opening.

Optionally, the flexible substrate may include a metal layer and a thickness of the metal layer may be approximately in a range of 0.1 μm to 0.5 μm.

Optionally, the flexible substrate may include a first flexible layer, a first barrier layer, the metal layer, a second barrier layer, and a second flexible layer in this order.

Optionally, a thickness of the first flexible layer or the second flexible layer may be approximately in a range of 0.2 μm to 0.6 μm, and a thickness of the first barrier or the second barrier may be approximately in a range of 0.05 μm to 0.3 μm.

Another embodiment of the present disclosure is a display apparatus including the display panel.

### BRIEF DESCRIPTION OF THE DRAWINGS

The drawings are intended to provide a further understanding of the technical solutions of the present disclosure, and are intended to be a part of the specification, and are used to explain the technical solutions of the present disclosure, and do not constitute a limitation of the technical solutions of the present disclosure.

FIG. 1 shows results of a flexible substrate after a stretching test in the related art;

FIG. 2 illustrates a schematic diagram of a pattern of the island and bridge structure;

FIG. 3 shows a schematic diagram of a display substrate according to one embodiment of the present disclosure;

FIG. 4 illustrates a schematic diagram of a display island, first openings, and first bridges in a flexible substrate according to one embodiment of the disclosure;

FIG. 5 illustrates a schematic diagram of a flexible substrate according to one embodiment of the present disclosure;

FIG. 6 illustrates a schematic diagram of a reinforced bridge structure according to one embodiment of the present disclosure;

FIG. 7 illustrates a schematic diagram of a reinforced bridge structure according to one embodiment of the present disclosure;

FIG. 8 illustrates a schematic diagram of a reinforced bridge structure according to one embodiment of the present disclosure;

FIG. 9 (a) provides a simulation result of a stretched flexible substrate in the related art;

FIG. 9 (b) provides a simulation result of a stretched flexible substrate according to one embodiment of the present application; and

FIG. 10 (a) shows a schematic diagram of a first bridge in a display region according to one embodiment of the present disclosure;

FIG. 10 (b) shows a schematic diagram of a dummy bridge at a boundary of the display region and the dummy region according to one embodiment of the present disclosure; and

FIG. 10 (c) shows a schematic diagram of a dummy bridge in the dummy region farther away from the display region according to one embodiment of the present disclosure.

### DETAILED DESCRIPTION

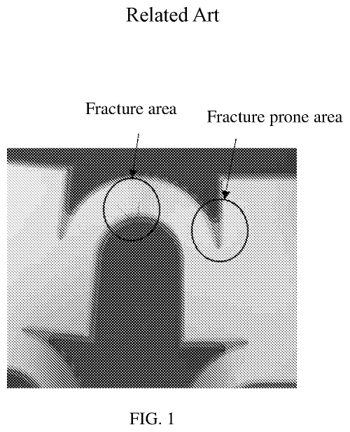

The present disclosure will be described in further detail with reference to the accompanying drawings and embodiments in order to provide a better understanding of the technical solutions of the present disclosure for those skilled in the art. Throughout the description of the disclosure, reference is made to FIGS. 1-10. When referring to the figures, like structures and elements shown throughout are indicated with like reference numerals.

In the description of the following embodiments, specific features, structures, materials or characteristics may be combined in any suitable manner in any one or more embodiments or examples.

The following terms, used in the present description and the appended claims, have the following definition.

An “opening density ratio” of an area of a display substrate is defined as a percentage of an area of all openings in the area of the display substrate. The larger the opening density ratio of the area of the display substrate, the smaller the Young's modulus of the area of the display substrate.

A “width” of a bridge at a point on one side of the bridge refers to a shortest distance from the point on one side of the bridge to the other opposite side of the bridge.

A flexible OLED display meets requirement of bending on a two-dimensional plane. However, a stretchable OLED display also needs meet requirement of deformation in a third dimension for a flexible display apparatus such as wearables.

A display panel may be fabricated on a flexible substrate using an island-bridge configuration to achieve the stretchability of functional apparatuses. In the island-bridge configuration, active areas including thin film transistors (TFTs) and electroluminescent components may be fabricated on the islands. Wire connections to the active areas may be fabricated along the bridges.

The island-bridge configuration is usually formed by cutting out a pattern of openings in a flexible substrate, thereby forming a plurality of islands separated by the openings and a plurality of bridges connecting the islands. The openings may accommodate large and reversible deformation applied on the stretchable and flexible display substrate. The stretching of the flexible substrate may pull the islands further apart from one another and widen the sizes of the openings. In the current stretchable display substrate, the sizes of these openings are usually the same. Thus, the opening density ratio of the central area of the display substrate is usually larger than the opening density ratio of the edge area of the display substrate. Accordingly, the Young's modulus of the central area of the display substrate is less than that of the edge area. As a result, when stretched, the flexible substrate may undergo larger deformation in the central area than in the edge area, thereby causing non-uniform deformation of the display substrate. Such non-uniform deformation may distort display images, thereby resulting in display abnormalities.

The stretchability of the display substrate also depends largely on the deformation of the bridges. The openings divide the flexible display into separate display islands or areas on which thin film transistors and electroluminescent components are fabricated. The separate display areas or islands are interconnected through the bridges. Large strains are usually generated on the bridges when the flexible substrate is stretched. Since the opening density ratio is greater in the central area than in the edge area of the display substrate, the Young's modulus of the central area is less than that of the edge area of the display substrate. As a result, the deformations of the bridges in different areas of the flexible substrate are not uniform. The bridges in the central area of the display substrate may experience larger deformation or strain than those in the edge area of the display substrate.

In the existing design, the bridge generally has a uniform width along the whole length of the bridge. Furthermore, sharp corners are usually formed at the junctions between the bridges and the islands. Such existing design tends to generate large strain or stress concentrations in different locations of the bridge, which tend to cause fracture or mechanical failure of the bridges.

FIG. 1 shows results of a flexible substrate after a stretching test in the related art. As shown in FIG. 1, the bridge has an arc-shaped configuration. When the flexible substrate is stretched, the concave side or inner side of the arc-shaped bridge is subjected to tensile strain and the convex side or outside of the arc-shaped bridge is subjected to compressive strain. Meanwhile, the display substrate near sharp corners at the junctions between the display islands and bridges experiences large strain concentration. As a result, the bridges are prone to fracture or fail near the sharp corners between the display islands and the bridges. Furthermore, as shown in FIG. 1, large strain concentration is observed at the inner side and the middle part of the bridge, thereby causing fracture or mechanical failure of the bridge.

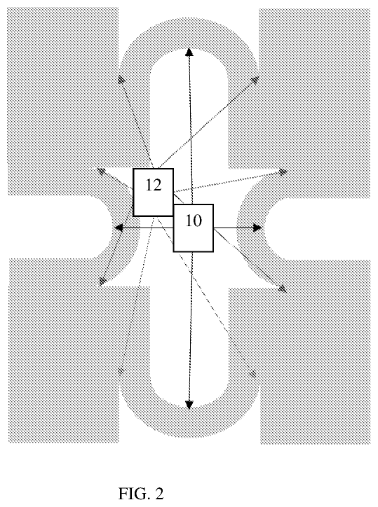

FIG. 2 illustrates a schematic diagram of a pattern of the island and bridge structure. The middle parts of the bridges, labeled as 10, and the areas near the corners at the junctions of the display islands and the bridges, labeled as 12, are prone to generate large strain or stress concentration. As such, to reduce the strain or stress concentrations, reinforcement or compensational structures may be needed at the middle parts of the bridges and/or the corner areas at the junctions of the display islands and the bridges.

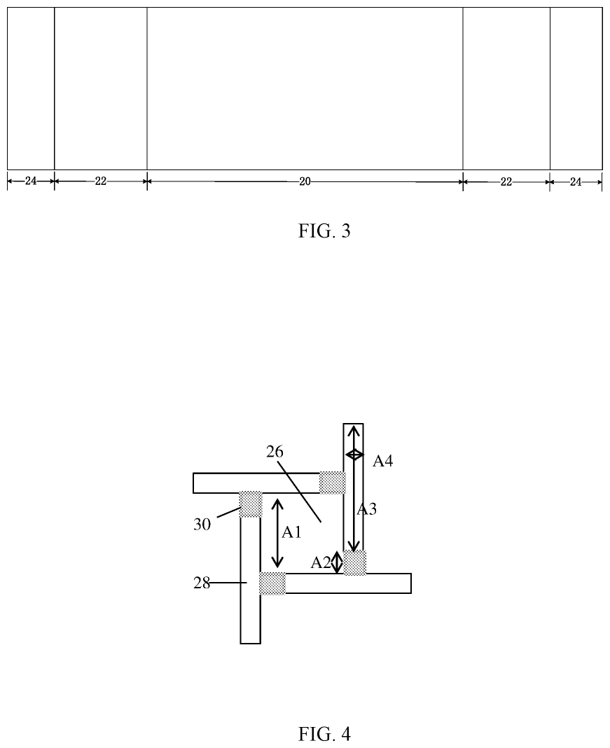

In one embodiment, the display panel includes a flexible substrate. FIG. 3 shows a schematic diagram of a display substrate according to one embodiment of the present disclosure. As shown in FIG. 3, the flexible substrate 100 includes a display region 20 and a dummy region 22. The dummy region 22 is arranged at the periphery of the display region. The display region 20 includes a plurality of display islands 26, a plurality of first openings 28 surrounding each of the display islands, a plurality of first bridges 30 connecting the display islands. A plurality of display units are formed on the plurality of display islands, respectively. The display unit may include an electroluminescent component as well as thin film transistors.

In one embodiment, the dummy region also includes a plurality of dummy islands, a plurality of dummy openings surrounding each of the plurality of dummy islands, and a plurality of dummy bridges connecting the plurality of dummy islands. The dummy region does not include any display units on the dummy islands.

In one embodiment, as shown in FIG. 3, the display substrate may further include a non-opening region 24 on a side of the dummy region 22 opposite from the display region 20. The non-opening region does not include any openings. The dummy region is at the periphery of the display region, serving as a transitional region to reduce the difference of the Young's modulus between the display region and the non-opening region due to their different opening density ratios. The transitional region may reduce the degree of distortion of the display substrate when the display panel is deformed. The size, shape, and density of the openings in the display region as well as in the dummy region may vary independently, depending on magnitude and distribution pattern of the tensile stress or strain applied on the display substrate in different applications.

FIG. 4 illustrates a schematic diagram of a display island 26, first openings 28, and first bridges 30 in a flexible substrate according to one embodiment of the disclosure. As shown in FIG. 4, the display island 26 has a square shape. The square display island 26 is surrounded by four rectangular first openings. A first bridge 30 is provided at each side of the display island to connect the display island to its neighboring display island. The display island constitutes an active region including functional layers and TFTs for display and is the main control area of the display backplate. The first openings are arranged around the active region and play an important role in increasing stretchability of the display backplate. First bridges are provided to connect different display islands, and wires connecting sources, drains, and gates of the TFTs on the display islands may be provided on the first bridges. Under stretching, the bridges may undergo large deformation. The structures of the display islands, first bridges and first openings on the display substrate are not limited to those in FIG. 4, and may be further designed, depending on magnitude and distribution pattern of the tensile stress or strain applied on the display substrate in different applications.

In one embodiment, with reference in FIG. 4, the display island 26 has a square shape with a side A1 approximately in a range of 200 μm to 600 μm, in which portions of an edge area of the display island are reserved for packaging. In one embodiment, the length A2 of each of the first bridges 30 is approximately in a range of 10 μm to 50 μm. Each of the openings 28 in the display region may have a rectangular or oblong shape with a length A3 less than 1000 μm and a width A4 less than 100 μm. In the dummy region, the dummy openings, dummy bridges, and dummy islands may have structures similar to those in the display region or may have irregular opening structures.

In one embodiment, an area of the first openings per unit area in the display region may be substantially the same as an area of the dummy openings per unit area in the dummy region. In one embodiment, the first openings may be arranged in the display region in a substantially same pattern as the dummy openings in the dummy region.

In one embodiment, the dummy openings may have a substantially same shape and size as the first openings. In one embodiment, each of the first openings has an oblong shape having a length in a range of 200 to 1000 μm and a width less than 100 μm. The length and width of the oblong shape refers to a length of the major axis and a length of the minor axis of the oblong shape, respectively. Each of the display islands may have a square shape having a side approximately in a range of 200 μm to 600 μm. A width of each of the first bridges may be approximately in a range of 10 μm to 50 μm. In one embodiment, a width of the dummy region is not less than 100 μm. A “width” of the dummy region refers to a shortest distance from a point at a boundary of the display region and the dummy region to an opposite boundary of the dummy region and the non-opening region.

In one embodiment, a width of each of the dummy bridges may be larger than a width of each of the first bridges.

The flexible substrate is usually made of polyimide (PI). The flexible substrate is usually first fabricated on a rigid substrate 29 such as a glass substrate and later removed from the rigid substrate. Currently, most of the flexible substrates adopt a flexible film structure having a single PI layer or a PI/barrier/PI layer. When stretched, the single PI layer or the three layered structure lacks sufficient ductility and flexibility.

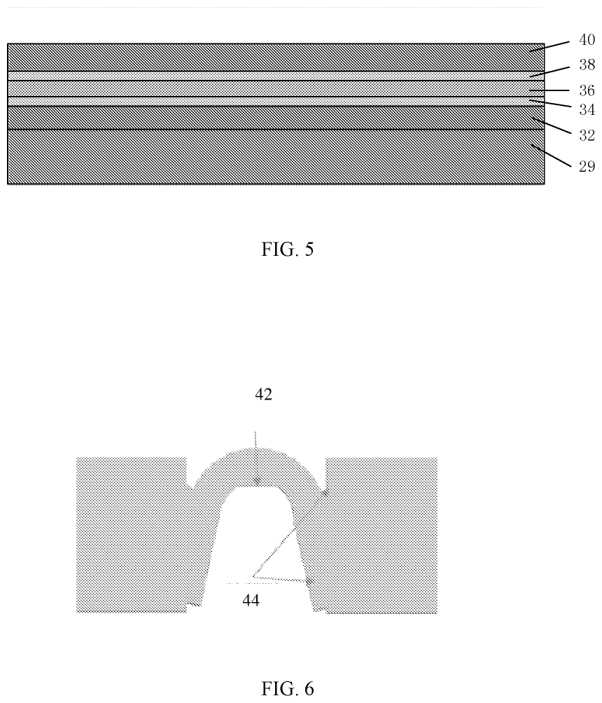

FIG. 5 illustrates a schematic diagram of a flexible substrate according to one embodiment of the present disclosure. As shown in FIG. 5, the flexible substrate includes a metal layer. A thickness of the metal layer may be approximately in a range of 0.1 μm to 0.5 μm.

In one embodiment, as shown in FIG. 5, a five-layer structure is provided to enhance the strength and toughness of the flexible substrate. The flexible substrate includes a first flexible layer 32, a first barrier layer 34, a metal layer 36, a second barrier layer 38, and a second flexible layer 40 in this order from the bottom to the top. The thickness of each first flexible layer 32 or each second flexible layer 40 may be appropriately in a range of 0.2 μm to 0.6 μm. The first barrier layer 34 and the second barrier layer 38 each may be made of SiNₓ, SiO₂ or a mixture of SiNₓ and SiO₂. The thickness of each first barrier layer 34 or each second barrier layer 38 may be appropriately in a range of 0.05 μm to 0.3 μm. As shown in FIG. 5, the metal layer 36 may be disposed in the flexible substrate to promote better toughness, ductility, and flexibility. The metal layer 36 may be provided between the two barrier layers. The thickness of the metal layer 36 may be appropriately in a range of 0.1 μm to 0.5 μm. The metal layer may be made of Cu, Al, Ti, Mo, or their metal alloys and fabricated by techniques such as vacuum deposition, chemical vapor deposition, or sputtering.

FIG. 6 illustrates a schematic diagram of a reinforced bridge structure according to one embodiment of the present disclosure. As shown in FIG. 6, each of the first bridges includes an arc shape connecting adjacent display islands and a force compensation area 42 at an inner side and a middle part of the arc shape. The force compensation area 42 is configured to reduce stress at the middle part of each of the first bridges. The shape and/or size the force compensation area are not limited in the present disclosure, and may have various shapes and/or sizes, depending on magnitude and distribution pattern of the tensile stress or strain applied on the display substrate in different applications.

In one embodiment, as shown in FIG. 6, the force compensation area 42 is added at the inner side and the middle part of the arc-shaped bridge so that the inner side of the force compensation area forms a straight line. As such, the width of the bridge is at the maximum at the middle point of the bridge. As a result, the strain or stress at the middle part of the bridge is reduced when the display substrate is stretched.

Furthermore, as shown in FIG. 6, the contacting area 44 between the first bridge and the first island may be reinforced by employing a fillet or a chamfer. As such, the angles of the sharp corner at the junctions of the bridges and the display islands become obtuse, and the contacting area between the display island and the bridge is increased. In one embodiment, a width of the contacting area 44 between the first bridge and the display island is larger than a width of the arc-shaped first bridge and is not more than an inner radius of the arc shape. As such, the strain concentration near the corners at the junctions of the bridges and the display islands is significantly reduced.

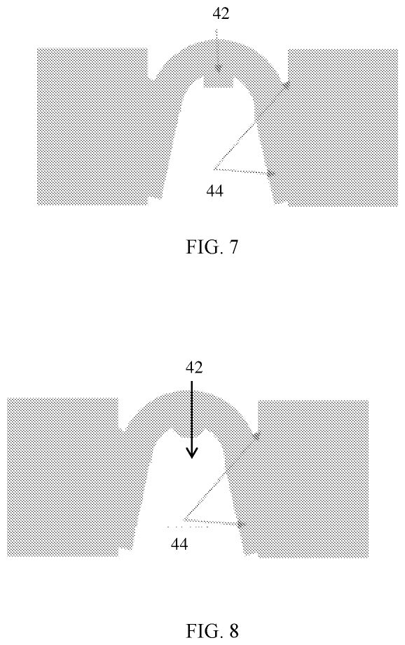

FIG. 7 illustrates a schematic diagram of a reinforced bridge structure according to one embodiment of the present disclosure. As shown in FIG. 7, the force compensation area 42 may have a rectangular shape added at a middle part of the arc-shaped bridge. As a result, the width of the bridge is at the maximum at the middle point of the bridge, and the strain or stress at the middle part of the bridge is significantly reduced when the display substrate is stretched.

FIG. 8 illustrates a schematic diagram of a reinforced bridge structure according to one embodiment of the present disclosure. As shown in FIG. 8, the force compensation area 42 may have a partial circular shape added at a middle part of the arc-shaped bridge. As such, the width of the bridge is at the maximum at the middle point of the bridge, and the strain or stress at the middle part of the bridge is significantly reduced when the display substrate is stretched.

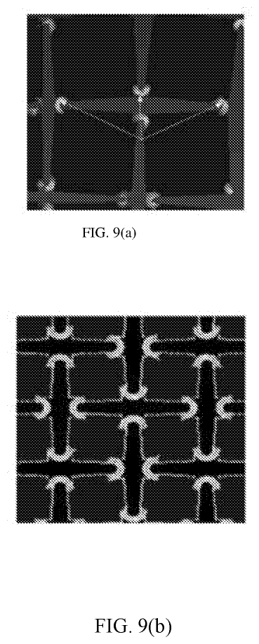

FIG. 9 (a) provides a simulation result of a stretched flexible substrate in the related art; and FIG. 9(b) provides a simulation result of a stretched flexible substrate according to one embodiment of the present disclosure. As shown in FIG. 9(a), for the uncompensated flexible substrate, large strain concentration was observed at the middle parts of the bridges and near the corners at the junctions of the bridges and the display islands. In contrast, as shown in FIG. 9(b), for compensated flexible substrate as shown in FIG. 8, strains are distributed uniformly on the bridges, and no large strain concentration is observed at the middle parts of the bridges and near the corners at the junctions of the bridges and the display islands. Since the areas prone to concentrated strains are reinforced in FIG. 9(b), the force compensation areas redistribute the strain more evenly onto the bridge, and the strain concentration is significantly reduced near the corners at the junction between the bridges and the display islands. Therefore, under the same stretching condition, the flexible substrate according to one embodiment of the present disclosure can effectively prevent fracture or mechanical failure of the display panel.

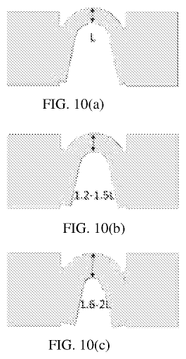

FIGS. 10(a) to 10(c) show schematic diagrams of bridges in a display region and a dummy region according to one embodiment of the present disclosure. The widths of the bridges in different regions of the flexible substrate may vary. In one embodiment, as shown in FIG. 10(a), in the display region, the width L of the first bridges is approximately in a range of 10 μm to 50 μm. As shown in FIG. 10(b), in the dummy region near the boundary between the display region and the dummy region, the dummy bridges are about 1.2 to 1.5 times as wide as the first bridges in the display region. That is, the width of each of the dummy bridges in the dummy area near the boundary between the display region and the dummy region is approximately 1.2 L to 1.5 L. As shown in FIG. 10(c), in the dummy region farther away from the display region, the dummy bridges are about 1.6 to 2 times as wide as the first bridges in the display region. That is, the width of each of the dummy bridges in the dummy region farther away from the display region is approximately 1.6 L to 2 L.

In one embodiment, widths of the plurality of dummy bridges in the dummy region may increase as distances of the plurality of dummy bridges from the display region increase. A width of one of the dummy bridges located closer to the display region may be smaller than a width of one of the dummy bridges located farther away from the display region.

According to some embodiments of the present disclosure, a stretchable display substrate is provided. The stretchability of the stretchable display substrate is improved from both macro and micro levels. At the macro level, both a display region and a dummy region are provided on the display substrate. The dummy region can effectively improve the uniformity of the display substrate. Furthermore, a metal layer or an inorganic film layer having a large Young's modulus in the middle of the PI substrate can improve the uniformity of Young's modulus of the display substrate. At the micro level, the contacting areas at the junctions of the islands and the bridges are reinforced to improve the reliability of the stretchable display substrate. Furthermore, force compensation areas are added at the inner sides and the middle parts of the bridges to reduce strain or stress levels thereto.

Another embodiment of the present disclosure further provides a display apparatus including the display panel according to one embodiment of the present disclosure.

Compared with the existing technique, the beneficial effects of the display apparatus provided in some embodiments of the present disclosure are the same as those of the display panel described above and are not repeated herein.

In one embodiment, the display apparatus may be any product or component having a display function, such as a mobile phone, a tablet computer, a television, a display, a notebook computer, a digital photo frame, or a navigator.

Unless otherwise defined, technical terms or scientific terms used in the present disclosure are intended to be in the ordinary meaning of those of ordinary skill in the art. The words “first,” “second” and similar words used in the present disclosure do not denote any order, quantity or importance, but are merely used to distinguish different components. The words “including” or “comprising” and the like mean that the element or the item preceding the word includes the element or item listed after the word and its equivalent and do not exclude other components or objects. “Upper,” “lower,” “left,” “right,” etc. are only used to indicate the relative positional relationship. When the absolute position of the object being described is changed, the relative positional relationship may also change accordingly.

The principle and the embodiment of the disclosure are set forth in the specification. The description of the embodiments of the present disclosure is only used to help understand the method of the present disclosure and the core idea thereof. Meanwhile, for a person of ordinary skill in the art, the disclosure relates to the scope of the disclosure, and the technical embodiment is not limited to the specific combination of the technical features, and also should covered other technical embodiments which are formed by combining the technical features or the equivalent features of the technical features without departing from the inventive concept. For example, technical embodiments may be obtained by replacing the features described above as disclosed in this disclosure (but not limited to) with similar features.

1. A display panel, comprising:
a flexible substrate comprising a display region and a dummy region; the dummy region being at periphery of the display region; the display region comprising a plurality of display islands, a plurality of first openings surrounding each of the plurality of display islands, a plurality of first bridges connecting the plurality of display islands, and a plurality of display units on the plurality of display islands, respectively;
wherein the dummy region comprises a plurality of dummy islands, a plurality of dummy openings surrounding each of the plurality of dummy islands, and a plurality of dummy bridges connecting the plurality of dummy islands, and the dummy region does not comprise display units.

2. The display panel according to claim 1, wherein an area of the first openings per unit area in the display region is substantially the same as an area of the dummy openings per unit area in the dummy region.

3. The display panel according to claim 1, wherein the plurality of first openings are arranged in the display region in a substantially same pattern as the plurality of dummy openings in the dummy region.

4. The display panel according to claim 1, wherein one of the plurality of dummy openings has a substantially same shape and size as one of the plurality of first openings.

5. The display panel according to claim 1, wherein a width of one of the plurality of dummy bridges is larger than a width of one of the plurality of first bridges.

6. The display panel according to claim 1, wherein a width of one of the plurality of dummy bridges located closer to the display region is smaller than a width of one of the plurality of dummy bridges located farther away from the display region.

7. The display panel according to claim 1, wherein widths of the plurality of dummy bridges increase as distances of the plurality of dummy bridges from the display region increase.

8. The display panel according to claim 1, wherein each of the plurality of first openings has a rectangular or oblong shape having a length less than 1000 μm and a width less than 100 μm, each of the plurality of display islands has a square shape having a side approximately in a range of 200 μm to 600 μm, and a width of each of the plurality of first bridges is approximately in a range of 10 μm to 50 μm.

9. The display panel according to claim 1, wherein a width of the dummy region is not less than 100 μm.

10. The display panel according to claim 1, wherein each of the plurality of first bridges comprises an arc shape connecting adjacent display islands and a force compensation area at an inner side and a middle part of the arc shape, and the force compensation area is configured to reduce strain at the middle part of each of the plurality of first bridges.

11. The display panel according to claim 10, wherein a width of each of the plurality of first bridges is at a maximum at the middle thereof.

12. The display panel according to claim 11, wherein an inner side of the force compensation area is a straight line.

13. The display panel according to claim 10, wherein the force compensation area has a rectangular shape or a partial circular shape.

14. The display panel according to claim 10, wherein a width of contacting area between a first bridge and a first island is larger than a width of an arc shape of the first bridge and is not more than an inner radius of the arc shape.

15. The display panel according to claim 14, wherein the contacting area between the first bridge and the first island is reinforced by employing a fillet or a chamfer.

16. The display panel according to claim 1, further comprising a non-opening region on a side of the dummy region opposite from the display region,
wherein the non-opening region does not comprise an opening.

17. The display panel according to claim 1, wherein the flexible substrate comprises a metal layer and a thickness of the metal layer is approximately in a range of 0.1 μm to 0.5 μm.

18. The display panel according to claim 17, wherein the flexible substrate comprises a first flexible layer, a first barrier layer, the metal layer, a second barrier layer, and a second flexible layer in this order.

19. The display panel according to claim 18, wherein a thickness of the first flexible layer or the second flexible layer is approximately in a range of 0.2 μm to 0.6 μm, and a thickness of the first barrier or the second barrier is approximately in a range of 0.05 μm to 0.3 μm.

20. A display apparatus comprising the display panel of claim 1.
